(19) United States
(12) Patent Application Publication
(10) Pub. No.: US 2018/0375301 A1
(43) Pub. Date: Dec. 27, 2018

(54) ION-GENERATING DEVICE

(71) Applicant: TEQOYA, Sceaux (FR)

(72) Inventors: Pierre GUITTON, Paris (FR); Jacques BRETON, Pessac (FR); Renaud MARCHAND, Villandraut (FR)

(21) Appl. No.: 15/780,878

(22) PCT Filed: Nov. 16, 2016
(86) PCT No.: PCT/FR2016/052977

§ 371 Date: Jun. 1, 2018

(30) Foreign Application Priority Data
Dec. 2, 2015 (FR) 1561761

(51) Int. Cl. H01T 19/04; H01T 23/00; H01J 37/08; H01J 27/20

(52) U.S. Cl. CPC H01T 19/04; H01J 27/20; H01J 37/08; H01T 23/00

(57) ABSTRACT

A device that includes at least one generator of ionized particles such as negative oxygen ions with a view to making breathed air more healthy. In order to regularize the generation of the ions, the device includes a grid-shaped structure made up of conductive segments at the mouths of the generators.

The present invention relates to a device for generating ions from a plasma, with the device having a radiation face on which is arranged at least one mouth of a particle emitter formed by a sheath brought to a first voltage in the extension of said mouth, a rod made of an electrically conductive material inserted into said sheath, with the mouth of said rod having a point brought to a voltage having a second polarity, with said voltages being provided by a high voltage circuit.

It is well known that the presence of ions, preferably negative ions, such as that of negative oxygen (O2⁻) has a beneficial effect on the health of living beings and contributes to the air pollution control. In the normal environment of an urban area, the concentration of such ions is rarely satisfactory. Artificially creating such negative ions has then been considered. Such devices are commercially available. It should be noted that the French patent document No. 2,722,923 discloses such a device which has the ability to create ions without generating ozone or nitrogen oxides in measurable amounts.

In this document, negative ions are created by forming nascent plasma from a point brought to a high voltage.

Although operational, this known device does not always provide for the creation of ions on a consistent basis, with the result that repeatability of the device performance could not be obtained during the manufacture thereof. A high sensitivity of the device to the materials such apparatus is made of could also be noted.

The object of the invention is therefore to obtain such plasma which ions are created from in a more stable and safer way.

For this purpose, the ionized particle generating device of the kind mentioned in the preamble is remarkable in that it comprises an electrically conductive structure located at the front face.

For greater efficiency, and operating with any material constituting the front face, such structure is, preferably but non-limitatively, in the form of a grid formed of segments having an elongate shape, the transverse dimension of which is smaller than the diameter of the mouths, and being positioned close to said mouths.

The following description accompanied by the appended drawings, all given by way of non-limiting example, will explain how the invention can be achieved. Among the drawings:

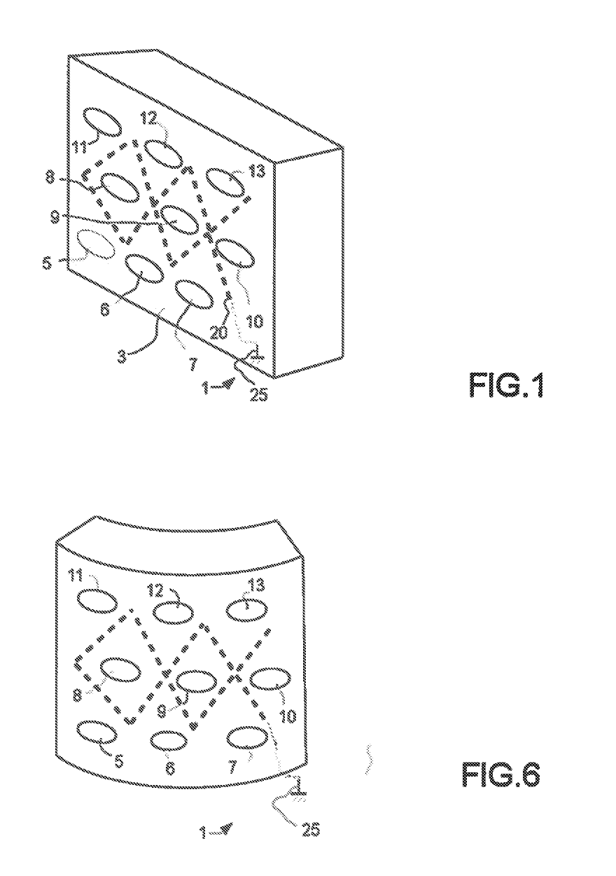

FIG. 1 shows a device according to the invention,

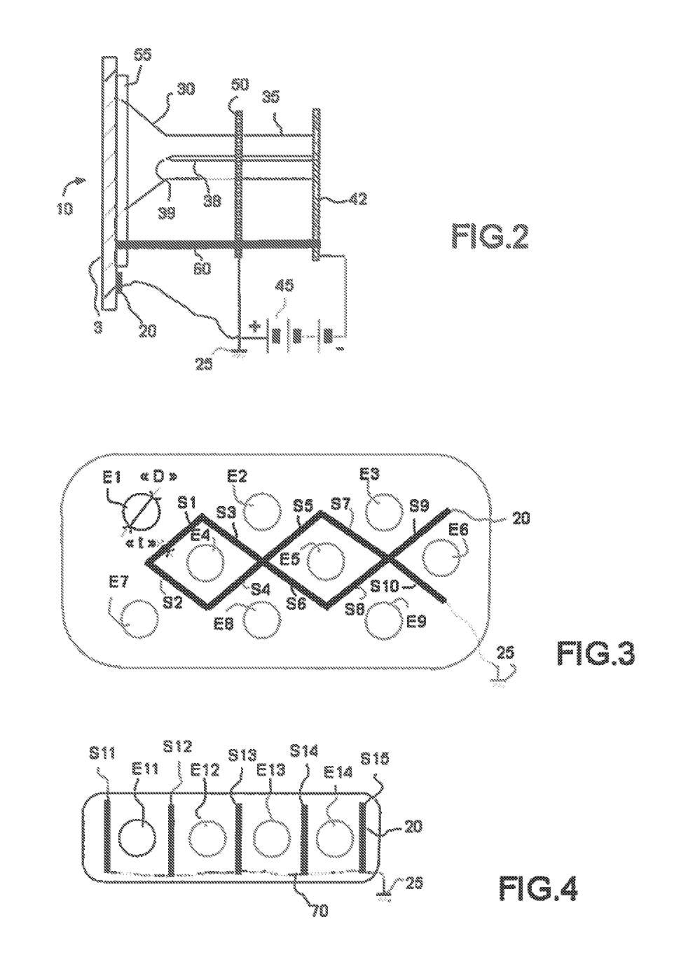

FIG. 2 shows a side view of a particle emitter,

FIG. 3 shows a first configuration of the structure proposed by the invention,

FIG. 4 shows a second configuration of the structure provided by the invention,

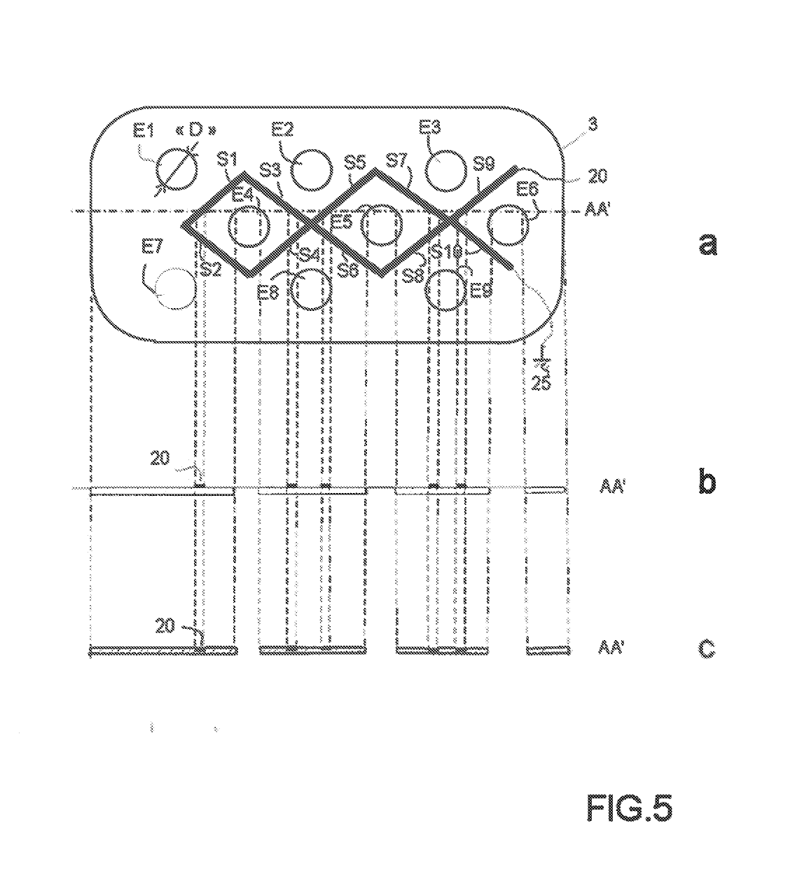

FIG. 5 shows embodiments of the device of the invention,

FIG. 6 shows another embodiment of the device of the invention.

In these figures, the common elements all have the same references in all the figures.

In FIG. 1, reference 1 refers to the device of the invention. The elements of such device are placed in a housing having a front radiation face 3, so-called the ions generation face. Different openings 5, 6, 7, 8, 9, 10 11, 12 and 13 are provided on such front face. The flow of ions is released outside through these openings. For this purpose, the openings communicate with a mouth of a particle emitter shown in details in FIG. 2. In practice, the devices according to the invention comprise between 4 and 24 particle emitters.

According to the invention, the device 1 is provided with a structure 20 made of an electrically conductive material. In the figure, the structure 20 is shown in dotted lines to indicate that it is positioned at the rear of the front face 3. This grid is connected to the ground 25 of the device 1.

FIG. 2 shows a side view of an ion emitter suitable for the invention. This emitter is assigned to the opening 10 of the front face 3. Of course, an identical emitter is assigned to each opening. The emitter of FIG. 2 comprises a mouth 30 having a conical shape which is connected to a tube 35 forming a sheath in which a rod 38 made of an electrically conductive material is placed. The first end of the rod terminates in a point 39 at the mouth 30 and the second end thereof is electrically connected to a plate 42 brought to a negative voltage generated by a high voltage generator 45. The voltage supplied has a value suitable for creating a corona effect.

A plate 50 provided with a passage for surrounding the sheath 35 is brought to the positive voltage of the generator 45. The plate 50 is thus at the ground potential 25. An output plane 55 has also been provided at the mouth 30. The structure 20 is placed on the inner face of the front face 3. This structure 20 may be sandwiched between said inner face and the output plane. Of course, the plates 42 and 50 may be common to all the emitters in the device of the invention. This can also apply to the output plane 55.

In an alternative embodiment, the output plane and the front face can be so combined that the structure can then be incorporated into the housing material. It should be noted that assembly pads such as the pad 60 which holds the various elements of the emitter against the front face have also been provided for.

According to another alternative solution, these pads may be used to attach the structure 20.

The structure 20, in a first embodiment, is shown in FIG. 3. This embodiment relates to a device having 9 ionized particles emitters. This structure consists of several segments S1 to S10 surrounding the 9 mouths E1 to E9 shown in this FIG. 3.

In a second embodiment, another structure 20 is shown in FIG. 4 and refers to a device with 4 emitters. In this case, the segments S11 to S15 do not surround the mouths E11 to E15 arranged in a straight line, but are positioned close thereto, on either side of the mouths E11 to E15.

All segments are brought to the ground potential 25. This is ensured by an electrical connection 70, shown in dotted lines in this figure, which connects same to the ground 25. These segments have an elongate shape, the transverse dimension “t” of which is smaller than the diameter “D” of the mouth. This is shown in FIG. 3 relative to S1 and E1 respectively.

The sequence network may also be continuous, i.e. in a single piece.

FIG. 5 shows alternative embodiments of the device of the invention, with the various possible positions of the structure 20 on the front face 3. FIG. 5a shows the front face 3, FIGS. 5b and 5c show a sectional view of the front plate 3 along the line AA′.

FIG. 5b shows that the structure 20 is bonded onto the front face 3. This structure can be produced using the printed circuit techniques or be obtained by depositing a conductive material such as a metal or a layer of a graphitized material.

In FIG. 5c, the structure 20 is positioned in a groove provided on said front face which provides some protection to the structure 20.

The thus arranged structure makes it possible to simply produce the devices of the invention having a rounded appearance with curved forms which makes same aesthetic and attractive to users (see FIG. 6).

It should also be noted that positive ions can be generated by reversing the polarity of the generator 45.

1-8. (canceled)

9. A device for generating ionized particles from a plasma, the device comprising:
a radiation face having at least one mouth of a particle emitter formed by a sheath brought to a first voltage and located in an extension of the at least one mouth;
a rod comprising an electrically conductive material inserted into the sheath and having a point brought to a voltage having a second polarity at the at least one mouth, with the voltages being developed by a high voltage circuit;
an electrically conductive structure located at the front face and being formed of segments having an elongate shape and being positioned in the vicinity of the at least one mouth.

10. The device according to claim 9, wherein the electrically conductive structure is electrically connected to a ground of the device.

11. The device according to claim 9, wherein the electrically conductive structure is formed of segments having an elongated shape that surround the at least one mouth.

12. The device according to claim 9, wherein a transverse dimension of the segments is smaller than a diameter of the at least one mouth and greater than a radius of curvature of the point.

13. The device according to claim 9, wherein the segments form a continuous network.

14. The device according to claim 13, wherein the segments are composed of a single conductive material.

15. The device according to claim 9, wherein the electrically conductive structure includes a deposited layer of conductive material on the radiation face.

16. The device according to claim 9, wherein the electrically conductive structure is positioned in grooves on the front face.

17. The device according to claim 9, wherein the device has a rounded appearance.
